(19) United States
(12) Patent Application Publication
(10) Pub. No.: US 2024/0389301 A1
(43) Pub. Date: Nov. 21, 2024

(54) SEMICONDUCTOR STRUCTURE, FABRICATION METHOD THEREOF, AND MEMORY SYSTEM

(71) Applicant: YANGTZE MEMORY TECHNOLOGIES CO., LTD., Wuhan (CN)

(72) Inventor: Hao ZHANG, Wuhan (CN)

(21) Appl. No.: 18/456,231

(22) Filed: Aug. 25, 2023

(30) Foreign Application Priority Data
May 16, 2023 (CN) 2023105623826

(51) Int. Cl. H10B 12/00

(52) U.S. Cl. CPC H10B 12/315; H10B 12/0335

(57) ABSTRACT

Implementations of the present disclosure provide a semiconductor structure, a fabrication method thereof, and a memory system. The semiconductor structure includes: a transistor, a contact located over the transistor and coupled with a first active area of the transistor; and a capacitive structure located over the contact, wherein an extending direction of a sidewall of the capacitive structure at an end proximate to the contact overlaps an extending direction of a sidewall of the contact, and one electrode of the capacitive structure is coupled with the contact.

### CROSS-REFERENCE TO RELATED APPLICATIONS

The present application claims priority to Chinese Patent Application No. 2023105623826, which was filed May 16, 2023, is titled “SEMICONDUCTOR STRUCTURE AND MANUFACTURING METHOD AND MEMORY SYSTEM,” and is hereby incorporated herein by reference in its entirety.

### TECHNICAL FIELD

The present disclosure relates to the field of semiconductor technology, and in particular to a semiconductor structure, a fabrication method thereof, and a memory system.

### BACKGROUND

In integrated circuits, a transistor in a semiconductor structure is widely used for a switching device or a driving device. For example, a memory cell of a dynamic random access memory (DRAM) may include a transistor and a capacitive structure (a storage capacitor), and the capacitive structure may be controlled by the transistor to enable data writing or reading.

The transistor and capacitive structure may be reduced in size to increase the degree of integration of memory cells, and thus improve the storage capacity of the DRAM. However, as the transistor and the capacitive structure shrink continuously, the fabrication difficulty of the transistor and the capacitive structure increases correspondingly.

### SUMMARY

In accordance with a first aspect of implementations of the present disclosure, a semiconductor structure is provided, the semiconductor structure including: a transistor; a contact located on the transistor and coupled with a first active area of the transistor; and a capacitive structure located over the contact, wherein an extending direction of a sidewall of the capacitive structure at an end proximate to the contact overlaps an extending direction of a sidewall of the contact, and one electrode of the capacitive structure is coupled with the contact.

In some implementations, at least a part of the capacitive structure and the contact are confined within one and the same opening.

In some implementations, the contact includes a connecting layer and a conductive part, and the connecting layer is located between the first active area and the conductive part.

In some implementations, the capacitive structure includes: a first sub capacitor and a second sub capacitor; and a first sidewall extending in a first direction and a second sidewall extending in a second direction crossing the first direction, wherein the second sidewall extends along an interface between the first sub capacitor and the second sub capacitor.

In some implementations, the semiconductor structure further includes: an insulating layer located over the first active area, wherein the capacitive structure penetrates through the insulating layer.

In some implementations, the insulating layer includes a first sub insulating layer and a second sub insulating layer; the first sub insulating layer is located between the second sub insulating layer and the contact; the first sub capacitor penetrates through the first sub insulating layer in a third direction perpendicular to the second direction and is coupled the contact; the second sub capacitor penetrates through the second sub insulating layer in the third direction; and the second sidewall extends along an interface between the first sub insulating layer and the second sub insulating layer.

In some implementations, a size of the second sub capacitor at an end proximate to the transistor in the second direction is smaller than a size of the first sub capacitor at an end away from the transistor in the second direction.

In some implementations, a conductivity of the connecting layer is higher than that of the first active area.

In some implementations, a thickness of the conductive part is larger than a thickness of the connecting layer in the third direction.

In some implementations, the thickness of the conductive part is larger than or equal to twice of the thickness of the connecting layer in the third direction.

In some implementations, the contact further includes a buffering layer, and the connecting layer is located between the buffering layer and the conductive part.

In some implementations, the first active area includes single crystal silicon or polysilicon; the connecting layer includes metal silicide; and the buffering layer includes single crystal silicon or polysilicon.

In some implementations, the capacitive structure includes: a first electrode, a dielectric layer and a second electrode disposed sequentially, wherein the first electrode is coupled with the contact, and a plurality of the capacitive structures are coupled through the second electrode.

In some implementations, the transistor includes: a semiconductor pillar, the first active area located at an end of the semiconductor pillar proximate to the capacitive structure; and a gate dielectric layer and a gate, wherein the gate dielectric layer is located between the semiconductor pillar and the gate.

In some implementations, the semiconductor structure further includes a stop layer located between the insulating layer and the contact, the capacitive structure also penetrating through the stop layer.

In accordance with a second aspect of implementations of the present disclosure, a memory system is provided, the memory system including: a memory device including one or more said semiconductor structures; and a memory controller coupled with the memory device and controlling the memory device.

In accordance with a third aspect of implementations of the present disclosure, a method of fabricating a semiconductor structure is provided, the method including: forming an insulating layer over a transistor; forming a first opening through the insulating layer, a first active area of the transistor exposed at a bottom of the first opening; forming a contact at the bottom of the first opening, the contact being coupled with the first active area; and forming a capacitive structure at least partially in the first opening, one electrode of the capacitive structure being coupled with the contact.

In some implementations, the first opening includes a first sub opening and a second sub opening, and the forming the first opening includes: forming the first sub opening through the first sub insulating layer, the first active area of the transistor exposed at a bottom of the first sub opening; forming the contact at the bottom of the first sub opening, the contact being coupled with the first active area; forming a sacrificial part in the first sub opening having the contact therein, a top surface of the sacrificial part being flush with the first sub insulating layer; forming a second sub insulating layer on the first sub insulating layer and the sacrificial part; forming the second sub opening through the second sub insulating layer in a third direction, wherein the sacrificial part is exposed at a bottom of the second sub opening; and removing the sacrificial part so that the first sub opening is exposed by the second sub opening.

In some implementations, the first opening has a third sidewall extending in a first direction and a fourth sidewall extending in a second direction that crosses the first direction, and the second direction is perpendicular to a penetrating direction of the first opening, wherein the fourth sidewall extends along an interface between the first sub insulating layer and the second sub insulating layer.

In some implementations, a size of a bottom of the second sub opening is smaller than a size of a top of the first sub opening in the second direction.

In some implementations, the forming the capacitive structure includes: forming a first electrode, a dielectric layer and a second electrode sequentially over a sidewall and a bottom of each of a plurality of the first openings, wherein the first electrodes are electrically isolated from each other, the second electrode continuously covers sidewalls and bottoms of a plurality of the first openings, and a plurality of the capacitive structures are coupled by the second electrode.

In some implementations, the forming the contact includes: forming a layer of buffering material at a bottom of the first opening; forming a layer of metal material on and in contact with the layer of buffering material; and thermally treating the layer of buffering material and the layer of metal material, both at least a part of the layer of buffering material and the layer of metal material forming a connecting layer; and forming a conductive part on the connecting layer.

In some implementations, the first active area includes single crystal silicon or polysilicon; the connecting layer includes metal silicide; and the layer of buffering material includes single crystal silicon or polysilicon.

In some implementations, the forming the transistor includes: forming a semiconductor pillar by etching a semiconductor layer; forming a gate dielectric layer at a side of the semiconductor pillar; forming a gate covering the gate dielectric layer, the gate dielectric layer located between the semiconductor pillar and the gate; and forming the first active area by doping an end of the semiconductor pillar.

### BRIEF DESCRIPTION OF THE DRAWINGS

FIGS. 1a to 1d are schematic diagrams illustrating a method of fabricating a semiconductor structure 100 in accordance with an example implementation.

FIG. 2 is a first schematic structural diagram illustrating a semiconductor structure 200 in accordance with an implementation of the present disclosure.

FIG. 3 is a second schematic structural diagram illustrating a semiconductor structure 200 in accordance with an implementation of the present disclosure.

FIG. 4 is a third schematic structural diagram illustrating a semiconductor structure 200 in accordance with an implementation of the present disclosure.

FIG. 5 is a schematic cross-sectional diagram illustrating a semiconductor structure 200 in accordance with an implementation of the present disclosure.

FIG. 6 is a schematic diagram of an example memory system including a semiconductor structure in accordance with an implementation of the present disclosure.

FIG. 7 is a schematic flowchart illustrating a method of fabricating a semiconductor structure 200 in accordance with an implementation of the present disclosure.

FIG. 8a to 8c are first schematic diagrams illustrating a method of fabricating a semiconductor structure 200 in accordance with an implementation of the present disclosure.

FIG. 9a to 9f are second schematic diagrams illustrating a method of fabricating a semiconductor structure 200 in accordance with an implementation of the present disclosure.

FIGS. 10a to 10c are schematic diagrams illustrating a method of fabricating a transistor in accordance with an example implementation.

### DETAILED DESCRIPTION

Technical solutions of the present disclosure will be described in detail hereafter in connection with accompanying drawings and specific implementations.

In implementations of the present disclosure, the terms “first”, “second”, etc. are used to distinguish similar objects from one another and not intended to indicate any particular sequence or precedence.

In implementations of the present disclosure, the phrase “A in contact with B” includes both a case in which A is in direct contact with B and a case in which A is in indirect contact with B with an intermediate component disposed therebetween.

In implementations of the present disclosure, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than a thickness of the continuous structure. For example, a layer can be located between any pair of horizontal planes at, or between, a top surface and a bottom surface of a continuous structure. A layer can extend horizontally, vertically, and/or along a tapered surface. Furthermore, a layer can include multiple sub layers.

The meaning of terms “on,” “over,” and “above” in the present disclosure should be interpreted in the broadest manner such that “on” not only means “on” something without any intermediate feature or layer (e.g., directly on something) but also includes the meaning of “on” something with an intermediate feature or a layer therebetween.

Although implementations are described in the specification, not every implementation includes an independent technical solution and description of the implementations in the specification is provided only for clarity. The specification should be taken as a whole by those skilled in the art, and the technical solutions in the implementations can be used in any suitable combinations to form other implementations that can be understood by those skilled in the art.

In a semiconductor structure provided by implementations of the present disclosure, a contact is disposed and coupled between a transistor and a capacitive structure, and an extending direction of a sidewall of the capacitive structure at an end proximate to the contact overlaps an extending direction of a sidewall of the contact, so that the capacitive structure is aligned with the contact with high precision, a void defect therebetween can be reduced, a coupling performance between an electrode and the contact can be improved, and a reliability of the device can be improved. In a fabrication process, the capacitive structure and the contact may be formed within one opening, and thus a sidewall of the capacitive structure and a sidewall of the contact extend along a sidewall of the opening, so that the capacitive structure and the contact are aligned with high precision, a coupling performance between an electrode and the contact can be improved, and a fabrication yield is improved.

In some semiconductor structures or semiconductor devices, a transistor is configured as a switching device or a load device for voltage regulation. For example, in a DRAM, a memory cell may include a transistor and a capacitive structure (a storage capacitor) coupled with the transistor. The capacitive structure includes two electrodes electrically isolated from each other, wherein one electrode (a first electrode) is coupled with an active area (source) of the transistor and the other electrode (a second electrode) may be grounded or supplied with another voltage (e.g., Vcc/2). The other active area (drain) of the transistor is coupled with a bit line. In some implementations, the source and drain of the transistor may be interchangeable.

In some implementations, logical 1 and 0 may be represented by a higher amount and a lower amount of charge, respectively, stored in the capacitive structure or by a larger difference and a smaller difference between the voltages at two ends of the capacitive structure. In an example, a voltage signal is applied to a gate of a transistor by a word line to control the transistor to turn on or off and in turn to select or deselect the capacitive structure, so that data information stored in the capacitive structure can be read through the bit line or data can be written into the capacitor through the bit line for storage.

When a DRAM memory cell is read or written, a voltage fluctuation on the bit line caused by charging and discharging of the capacitive structure is relatively smaller, a duration of the voltage fluctuation is also very short, and charging and discharging signals sensed by the bit line are also relatively weaker, therefore a relatively higher performance of coupling between the capacitive structure and the transistor is demanded.

The semiconductor structure in implementations of the present disclosure may be a DRAM or may at least include some devices in a DRAM. It is applicable to a double data rate synchronous dynamic random access memory (DDR SDRAM) complying with a DDR4 memory specification or a DDR5 memory specification and a DDR SDRAM complying with a LPDDR5 memory specification. It is to be noted that implementations of the present application are not limited to DRAM and can be applied in any case in which a transistor is coupled with a capacitive structure. In the following description, an explanation is given with a DRAM taken as an example for clarity.

In an example implementation of the present disclosure, an example semiconductor structure 100 is provided, in which a contact is disposed between a capacitive structure and a transistor to reduce a contact resistance therebetween and thus improve performance of coupling between the capacitive structure and the transistor and in turn reliability of the device. The fabrication method of the example semiconductor structure 100 includes the following operations.

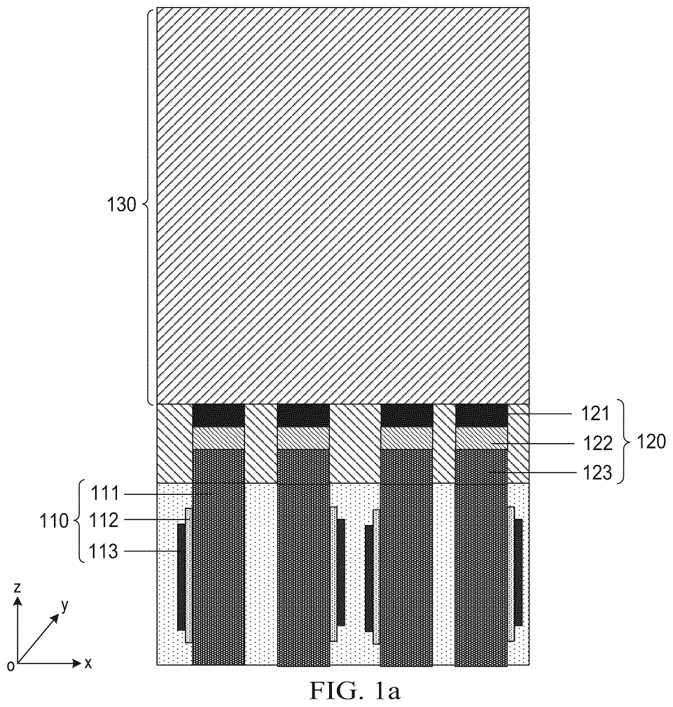

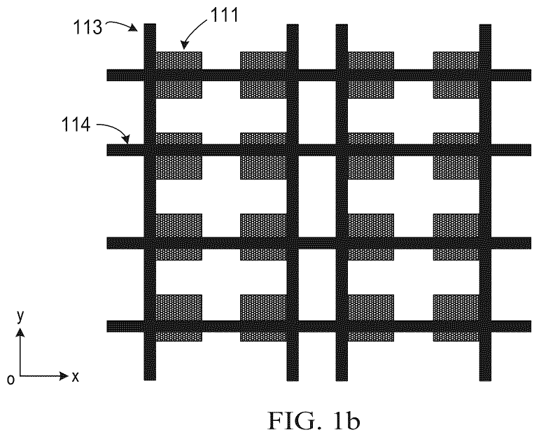

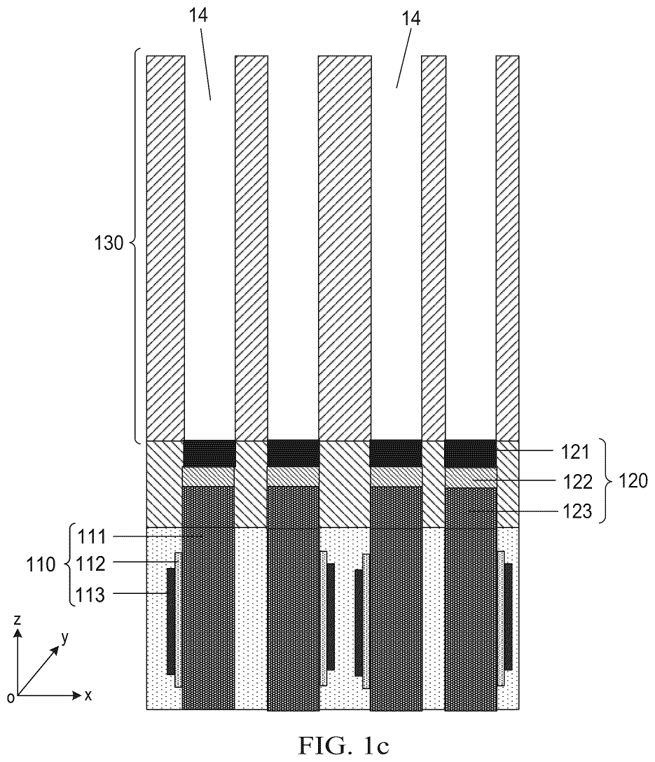

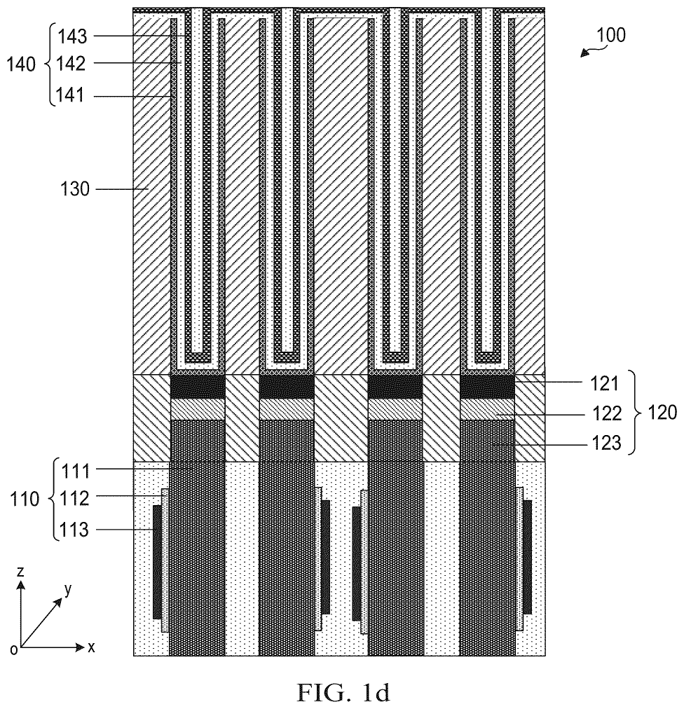

With reference to FIG. 1a, a transistor 110 is provided, and a contact 120 is formed over the transistor 110. The transistor 110 may be a vertical transistor that includes a semiconductor pillar 111 extending in a z direction. The semiconductor pillar 111 has a first active area and a second active area identically doped and located at the two ends of the semiconductor pillar 111 in the z direction. One of the first and second active areas is a source and the other is a drain. A region of the semiconductor pillar 111 between the first active area and the second active area may also be doped with a doping type opposite to that of the first active area, and may act as a channel of the transistor 110. A gate dielectric layer 112 and a gate 113 are disposed at a side of the semiconductor pillar 111 with the gate dielectric layer 112 located between the gate 113 and the semiconductor pillar 111 and the gate 113 covering at least part of the channel.

In some implementations, the gate 113 may be located at one side of the semiconductor pillar 111, and one gate 113 controls one transistor 110. Alternatively, a plurality of gates 113 may be disposed at four sides of the semiconductor pillar 111. For example, two gates 113 are disposed at opposite sides of the semiconductor pillar 111 in an x direction and control one transistor 110. In this case, if one gate 113 fails, the other gate 113 can still control the transistor 110, improving reliability. In some other implementations, the gate 113 may be a gate-all-around structure, e.g., the gate 113 surrounds the four sides of the semiconductor pillar 111, and the semiconductor pillar 111 penetrates through the gate 113 to improve control of the channel by the gate 113.

Implementations of the present disclosure are not limited in the arrangement and number of transistor 110. The gate 113, as a word line 113, may extend in a y direction or in a direction at an angle with respect to the y direction. A word line may connect a plurality of transistors 110 in series in its extending direction. A bit line 114 extends in a direction intersecting the extending direction of the word line, and connects a plurality of transistors 110 in series in its extending direction. The transistor 110 at an intersection of a word line and a bit line may be selected by selecting the word line and the bit line. For example, FIG. 1b shows a partial perspective view, seen from the z direction, that illustrates transistors and bit lines. A gate 113 extends in the y direction and a bit line 114 extends in a direction perpendicular to the extending direction of the word line 113, e.g., in the x direction. Alternatively, the bit line 114 may extend in a direction at an angle with respect to the x direction. It is to be noted that FIG. 1b, as a perspective view, only shows a schematic projection of semiconductor pillars 111, gates 113 and bit lines 114 on the xoy plane along the z direction. The bit line 114 is located at a position below the semiconductor pillar 111 in FIGS. 1a and 1s coupled with the second active area of the semiconductor pillar 111. Implementations of the present disclosure are not limited in the number and arrangement of the semiconductor pillar 111.

Illustratively, the gate 113 includes, but is not limited to, tungsten, platinum, gold, silver, copper, aluminum, chromium, nickel, titanium or any other conductive material. The gate dielectric layer 112 includes, but is not limited to, silicon oxide, silicon nitride, silicon oxynitride, aluminum oxide or any other insulating material. The semiconductor pillar 111 may include, but is not limited to, silicon, germanium or any other semiconductor material. The first electrode 141 may include the same material as the second electrode 143, or include a different material from the second electrode 143. The present disclosure is not limited in this respect.

In some implementations, as shown in FIG. 1a, an insulating layer 130 is formed over the contact 120. The insulating layer 130 may include a single-layer structure or a multi-layer structure including a plurality of sub insulating layers, or may include a plurality of layers such as an etch mask layer, an etch rate regulation layer, or the like.

As shown in FIG. 1c, an opening 14 may be formed through the insulating layer 130, and the contact 120 is exposed at the bottom of the opening 14.

As shown in FIG. 1d, a capacitive structure 140 is formed in an opening 14. In an example, the opening 14 is filled with a conductive material, and then a first electrode 141 is formed to cover a sidewall and bottom of the opening 14; a dielectric layer 142 is formed to cover the first electrode 141; and a second electrode 143 is formed to cover the dielectric layer 142. Here, the first electrode 141 is coupled with the contact 120.

Illustratively, the first electrode 141 and the second electrode 143 include, but is not limited to, tungsten, platinum, gold, silver, copper, aluminum, chromium, nickel, titanium or any other conductive material. The dielectric layer 142 includes, but is not limited to, silicon oxide, silicon nitride, silicon oxynitride, aluminum oxide or any other insulating material. The first electrode 141 may include the same material as the second electrode 143, or include a different material from the second electrode 143. The present disclosure is not limited in this respect.

In some implementations, the first electrode 141 may include a metal material to obtain a higher load voltage. The metal material directly contacts and couples with the semiconductor material in the semiconductor pillar 111. This will cause a relatively larger potential barrier between these two materials and in turn cause a relatively higher contact resistance, degrading the coupling performance. In implementations of the present disclosure, a contact 120 is disposed between a capacitive structure 140 and a transistor 110, and the contact 120 may include a metal-semiconductor compound material to reduce a surface potential barrier, and thus to reduce a contact resistance. Illustratively, when the semiconductor pillar 111 of the transistor 110 includes a silicon-based semiconductor material, the contact 120 may include a metal silicide; and when the semiconductor pillar 111 of the transistor 110 includes a germanium-based semiconductor material, the contact 120 may include a metal germanide.

In some implementations in which the semiconductor pillar 111 of the transistor 110 includes, e.g., a silicon-based semiconductor material, the contact 120 may include a single layer of material, and the contact 120 may include a single layer of metal silicide. In some implementations, as shown in FIG. 1a, the contact 120 may include multiple layers of materials, for example, a conductive part 121 and a connecting layer 122. The conductive part 121 may include a material that is the same as or similar to that of the first electrode 141, e.g., tungsten. The connecting layer 122 includes a metal silicide, such as tungsten silicide, titanium silicide or the like. The connecting layer 122 is located between the transistor 110 and the capacitive structure 140. The conductive part 121 is coupled to and in contact with the first electrode 141 of the capacitive structure 140 to reduce the contact resistance with the first electrode 141, and provide a physical support to the capacitive structure 140. The conductive part 121 also serves as an etch stop layer during the etching of the opening in FIG. 1c, so as to reduce damage to the transistor 110 and the connecting layer 122 during the etching. The connecting layer 122 is coupled to and in contact with the transistor 110 to reduce the contact resistance with the transistor 110.

In some other implementations, as shown in FIG. 1a, a buffering layer 123 is also included in the contact 120, wherein the buffering layer 123 is located between the connecting layer 122 and the transistor 110. The buffering layer 123 includes silicon left after the formation of metal silicide for the connecting layer 122 and no obvious physical interface may exist between the connecting layer 122 and the buffering layer 123 in a real device. In this implementation, silicon may be silicon having any crystalline state, including, but is not limited to, single crystal silicon or polysilicon, or amorphous silicon or ion-doped silicon.

In some implementations, as also shown in FIG. 1c, to have a larger contact area between the first electrode 141 and the contact 120, the opening 14 should be in alignment with the contact 120 in the z direction as much as possible to completely expose the top surface of the contact 120 by the opening 14, so that the contact area between the first electrode 141 and the contact 120 may be increased and the contact resistance therebetween may be reduced. In some example implementations, there is an error in alignment between the opening 14 and the contact 120. For example, when the depth of the opening 14 is increased to increase the area, in which the first electrode 141 and the second electrode 143 face each other, so as to increase capacitance, the alignment error may be worse, which reduces the contact area between the first electrode 141 and the contact 120 and further reduces the fabrication yield.

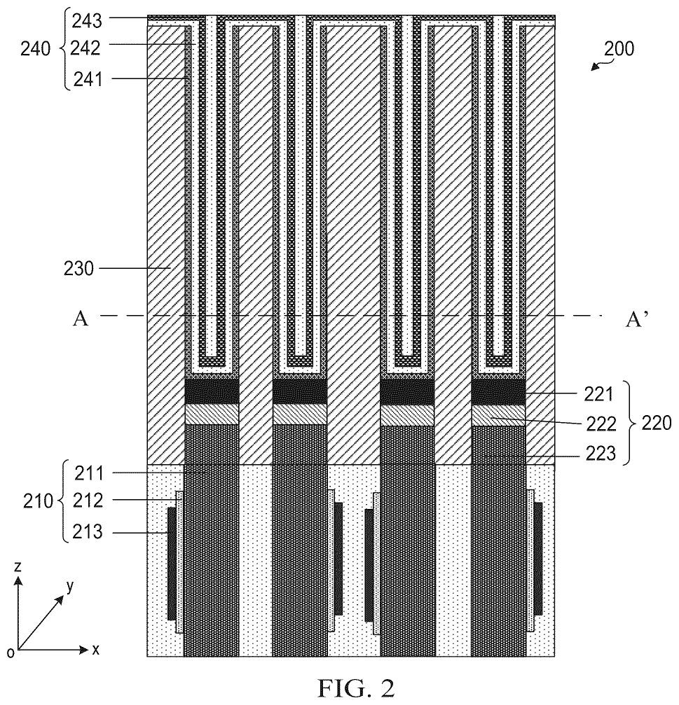

In view of this, implementations of the present disclosure provide a semiconductor structure and a fabrication method thereof, in which the contact and the capacitive structure are formed in one and the same opening, so that the difficulty of aligning the capacitive structure with the contact is reduced, and meanwhile the contact area between the capacitive structure and the contact is increased, reducing the contact resistance and improving reliability. With reference to FIG. 2, a semiconductor structure 200 includes: a transistor 210; a contact 220 located on the transistor 210 and coupled with a first active area of the transistor 210; and a capacitive structure 240 located over the contact 220, wherein an extending direction of a sidewall of the capacitive structure 240 at an end proximate to the contact 220 overlaps an extending direction of a sidewall of the contact 220, and one of electrodes of the capacitive structure 240 is coupled with the contact 220.

In implementations of the present disclosure, the first direction may include the z direction in the figures or a direction at an angle with respect to the z direction, and the first direction runs through the xoy plane. The second direction may include the x direction and the third direction may include the y direction.

The transistor 210 in the implementations of the present disclosure may include various transistors, for example, a vertical transistor 210 shown in FIG. 2. With reference to FIG. 2, the transistor 210 includes a semiconductor pillar 211 extending in the z direction and having a first active area and a second active area of the same doping type at its two ends respectively in the z direction. One of the first and second active areas is a source and the other is a drain. A region of the semiconductor pillar 211 between the first active area and the second active area may also be doped with a doping type opposite to that of the first active area and can act as a channel of the transistor 210. For example, the first and second active areas may be n-type doped and the channel may be p-type doped. Or the first and second active areas may be p-type doped and the channel may be n-type doped. A gate dielectric layer 212 and a gate 213 are disposed at a side of the semiconductor pillar 211, with the gate dielectric layer 212 located between the gate 213 and the semiconductor pillar 211 and the gate 213 covering at least part of the channel.

In some implementations, the gate 213 may be located at one side of the semiconductor pillar 211 and one gate 213 controls one transistor 210. Alternatively, a plurality of gates 213 may be disposed at four sides of the semiconductor pillar 211. For example, two gates 213 are disposed at opposite sides of the semiconductor pillar 211 in the x direction and control one transistor 210. In this case, if one gate 213 fails, the other gate 213 can still control the transistor 210, improving reliability. In some other implementations, the gate 213 may be a gate-all-around structure, for example, the gate 213 surrounds the four sides of the semiconductor pillar 211, and the semiconductor pillar 211 penetrates through the gate 213 to improve control of the channel by the gate 213. Implementations of the present disclosure are not limited in the arrangement and number of transistor 210. The gate 213, as a word line, may extend in the y direction or in a direction at an angle with respect to the y direction. A word line may connect a plurality of transistors 210 in series in its extending direction. A bit line extends in a direction intersecting the extending direction of the word line and connects a plurality of transistors 210 in series in its extending direction. For example, the transistor 210 at an intersection of a word line and a bit line may be selected by selecting the word line and the bit line.

The transistor 210 in the implementation of the present disclosure as shown in FIG. 2 is a vertical transistor extending in the z direction, and may be a transistor device serving as a switch, wherein a conductivity of a channel of the transistor device is controlled by a gate of the transistor device. There is no limitation on the physical forms of the transistor 210. In some other implementations, the transistor 210 may be a planar transistor 210, which has a first active area, a channel and a second active area arranged in the xoy plane and has the first active area coupled with the capacitive structure 240 through a conductive plug or a wire extending in the z direction.

With continuous reference to FIG. 2, the capacitive structure 240 may extend in the z direction and may have an orthographic projection in the z direction with a shape of circle, ellipse, rectangle or any other irregular shape, which is not limited in the implementations of the present disclosure. The capacitive structure 240 has two opposite ends in the z direction. An end in the negative z direction is relatively proximate to and coupled with the contact 220, and an end in the positive z direction is relatively further away from the contact 220. In order to explain implementations of the present disclosure in more detail, in the z direction, the end of the capacitive structure 240 relatively proximate to the contact 220 may be defined to occupy 0-20% of the whole length of the capacitive structure 240, e.g., extend 20% of the whole length of the capacitive structure 240 from the bottom of the capacitive structure 240 toward the positive z direction. For example, the portion of the capacitive structure 240 within this range of length is defined as the end of the capacitive structure 240 relatively proximate to the contact 220. The range of length is only an example, and in some implementations, and a smaller range of length may be employed.

A sidewall of the capacitive structure 240 at an end proximate to the contact 220 may extend in the z direction or in a direction at an angle with respect to the z direction, with the extending direction running through the xoy plane; and the extending direction of the sidewall in this portion overlaps the extending direction of the sidewall of the contact 220. The overlapping extending direction may be in the same plane. For example, at a contact interface between the capacitive structure 240 and the contact 220, a part of the sidewall of the capacitive structure 240 and a part of the sidewall of the contact 220 may extend in one plane, so that the capacitive structure 240 and the contact 220 are aligned with high precision, reducing the void defects therebetween and improving the coupling performance between the electrode and the contact 220.

In some implementations, the capacitive structure 240 and the contact 220 are confined within one and the same opening.

In some implementations, in fabrication of the capacitive structure 240, an insulating layer 230 is deposited on the transistor 210, and an opening is formed through the insulating layer 230 to expose the first active area of the transistor 210. The contact 220 and capacitive structure 240 are formed in the opening. The sidewall of the contact 220 extends over the sidewall of the opening and the sidewall of the capacitive structure 240 also extends over the sidewall of the opening, so that the extending direction of the sidewall of the capacitive structure 240 and the extending direction of the sidewall of the contact 220 overlap.

In some implementations, one semiconductor structure may include a plurality of capacitive structures 240 and a plurality of contacts 220, wherein one capacitive structure 240 and one contact 220 are formed in the same one opening, and one capacitive structure 240 is coupled with one corresponding contact 220.

In some implementations, the capacitive structure 240 includes: a first electrode 241, a dielectric layer 242 and a second electrode 243 disposed sequentially in the x direction, with the first electrode 241 being coupled with the contact 220.

In some implementations, as shown in FIG. 2, the plurality of capacitive structure 240 are coupled by the second electrode 243.

In some example implementations, the second electrode 243 has a shape of cylinder. The dielectric layer 242 surrounds a side and bottom of the second electrode 243 and the first electrode 241 surrounds a side and bottom of the dielectric layer 242. The dielectric layer 242 electrically isolates the first electrode 241 from the second electrode 243. The first electrode 241 is coupled with the contact 220 and may be supplied with a voltage (e.g., Vcc) through a bit line and the transistor 210, and the second electrode 243 may be grounded or supplied with another voltage (e.g., Vcc/2). The capacitive structure 240 in this implementation may be used independently, and one transistor may be configured to control one capacitive structure 240.

In some examples, the second electrode 243 is not coupled with transistor 210 directly and is not to be selected or deselected. When the capacitive structure 240 is selected, the second electrode 243 has the same load voltage or is grounded. When the capacitive structure 240 is deselected, the second electrode 243 may be supplied with no voltage or may remain grounded. As a result, when the capacitive structures 240 are arranged in an array, all of the second electrodes 243 may be coupled in series through a conductive structure including a conductive layer or a conductive wire. In some implementations, it is also possible to couple only a number n of second electrodes 243 and thus a plurality of capacitive structures 240 are coupled through these second electrodes 243. This equals to increasing the area of the second electrode 243. In this case, when the n capacitive structures 240 are accessed, the transistors 210 corresponding to the n capacitive structures 240 have to be turned on simultaneously, diversifying usage scenarios of the capacitive structures 240. Here, n is larger than or equal to 2.

In some implementations, as shown in FIG. 2, the capacitive structure 240 further includes a core that may comprise a material including, but is not limited to, silicon oxide, silicon nitride, silicon oxynitride, aluminum oxide or any other insulating material. The core has a shape of cylinder. The second electrode 243 surrounds a side and bottom of the core, the dielectric layer 242 surrounds a side and bottom of the second electrode 243, and the first electrode 241 surrounds a side and bottom of the dielectric layer 242. The core may have a void therein.

In FIG. 2, the n capacitive structures 240 may include n first electrodes 241 isolated from each other and one second electrode 243. At the top of the capacitive structure 240, the first electrode 241 has no a part extending in the x direction, and each first electrode 241 is a separate structure, and the second electrode 243 has a part extending in the x direction, so that the second electrode 243 extends continuously over n capacitive structures 240 to couple the n capacitive structures 240 together. The dielectric layer 242 between the first electrodes 241 and the second electrode 243 may extend in the same way as the second electrode 243. The second electrode 243 covers the dielectric layer 242 and is conformal to the dielectric layer 242. The dielectric layer 242 electrically isolates the second electrode 243 from the first electrodes 241.

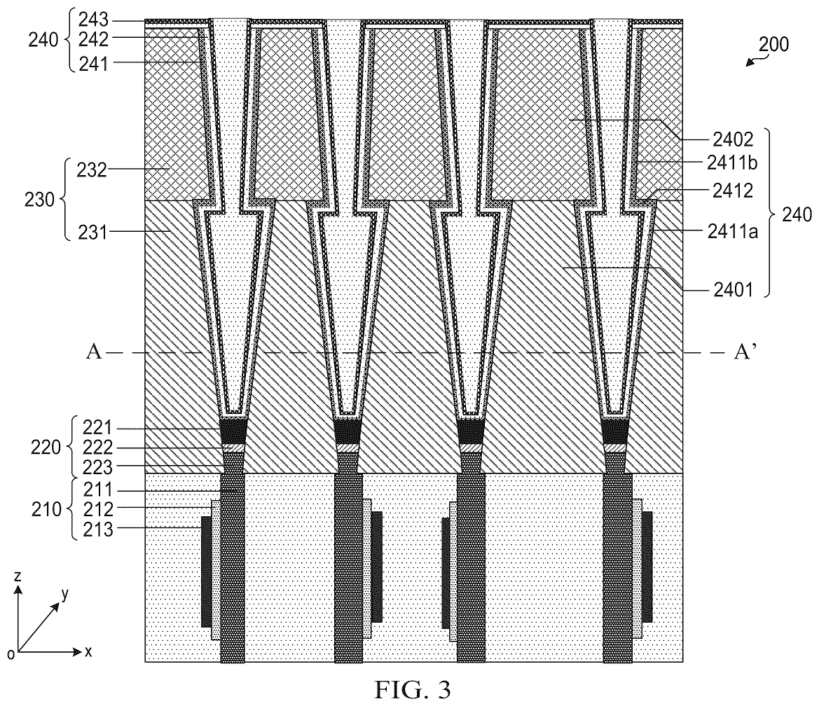

In some implementations, as shown in FIG. 3, a capacitive structure 240 includes: a first sub capacitor 2401 and a second sub capacitor 2402; and a first sidewall 2411a (2411b) extending in a first direction and a second sidewall 2412 extending in a second direction crossing the first direction, wherein the second sidewall 2412 extends along an interface between the first sub capacitor 2401 and the second sub capacitor 2402.

In some implementations, as shown in FIGS. 2 and 3, the semiconductor structure further includes an insulating layer 230 located over the first active area, wherein the capacitive structure 240 penetrates through the insulating layer 230.

The insulating layer 230 is configured to support the capacitive structure 240 and electrically isolate the first electrodes 241 from each other, and may comprise a single layer of insulating material as shown in FIG. 2 or multiple layers of insulating materials as shown in FIG. 3.

In FIG. 3, the capacitive structure 240 may include a first sub capacitor 2401 and a second sub capacitor 2402, with the first sub capacitor 2401 located between the contact 220 and the second sub capacitor 2402. The first sub capacitor 2401 and the second sub capacitor 2402 may be fabricated separately, which can reduce difficulty of fabrication especially when the capacitive structure 240 has a relatively larger height in the z direction. With the first electrode 241 taken as an example, the first sub capacitor 2401 may include a first sub electrode, and the second sub capacitor 2402 may include a second sub electrode, the first sub electrode being coupled with the second sub electrode and the first sub electrode being coupled with the contact 220. The dielectric layer 242 and the second electrode 243 of these two sub capacitors will not be further detailed.

In some implementations, the first sub capacitor 2401 and the second sub capacitor 2402 are formed simultaneously, for example, the first sub electrode and the second sub electrode are formed in the same one opening, and the first sub electrode and the second sub electrode have no obvious interface therebetween and may be a continuous layer formed by the same deposition process. When the capacitive structure 240 having a relatively larger height is fabricated, the etched aspect ratio of the opening to be formed in the insulating layer 230 increases and the difficulty of etching increases. In view of this, a first sub opening 261 may be formed first and then a second sub opening 262 is formed, wherein the first sub opening 261 and the second sub opening 262 are in communication with each other in the z direction and may form a whole opening with a larger depth in which the contact 220 and capacitive structure 240 will be formed.

In an etching process to obtain an opening with a larger aspect ratio, due to the loading effect of the etching, the size of the opening at the top in the x direction is larger than the size of the opening at the bottom in the x direction and thus the size of the formed capacitive structure 240 at the top in the x direction is larger than the size of the capacitive structure 240 at the bottom in the x direction. In FIG. 3, when the bottom of the second sub capacitor 2402 is aligned and coupled with the top of the first sub capacitor 2401 in the z direction, the size of the bottom of the second sub capacitor 2402 in the x direction is smaller than the size of the top of the first sub capacitor 2401 in the x direction. At the interface between the first sub capacitor 2401 and the second sub capacitor 2402, due to the difference in sizes in the x direction, a step is formed at the interface between these two sub capacitors. The first direction may be the z direction or a direction at an angle with respect to the z direction, and may run through the xoy plane. The first sidewall 2411a (2411b) may extend in the first direction and the second sidewall 2412 may extend in the x direction. The first sidewall and the second sidewall are defined with respect to the whole capacitive structure 240. The first sidewall may include the first portion 2411a in the first sub capacitor 2401 and the second portion 2411b in the second sub capacitor 2402, and the second sidewall 2412 may serve as the interface between the first sub capacitor 2401 and the second sub capacitor 2402 or between the first portion 2411a and the second portion 2411b.

In some implementations, as shown in FIG. 3, the insulating layer 230 includes a first sub insulating layer 231 and a second sub insulating layer 232, with the first sub insulating layer 231 located between the second sub insulating layer 232 and the contact 220.

The first sub capacitor 2401 penetrates through the first sub insulating layer 231 in the third direction and is coupled the contact 220, and the second sub capacitor 2402 penetrates through the second sub insulating layer 232 in the third direction. The second sidewall extends along the interface between the first sub insulating layer 231 and the second sub insulating layer 232. The third direction is perpendicular to the second direction.

In FIG. 3, the penetrating direction of the first sub capacitor 2401 and the second sub capacitor 2402 may be the z direction, and the first sub capacitor 2401 is located between the second sub capacitor and the contact 220. The penetrating direction of the first sub capacitor 2401 may be different from the penetrating direction of the second sub capacitor 2402. The former may be the z direction and the later may be a direction at an angle with respect to the z direction. The second sub capacitor 2402 penetrates through the second sub insulating layer 232 and then is coupled with the first sub capacitor 2401.

In some implementations, the first sub capacitor 2401 and the second sub capacitor 2402 may be formed simultaneously and their sidewalls may be a continuous structure. The boundary between the first sub capacitor 2401 and the second sub capacitor 2402 may be at the boundary between the first sub insulating layer 231 and the second sub insulating layer 232, and may be at the second sidewall extending in the x direction.

In some implementations, when the first sub insulating layer 231 and the second sub insulating layer 232 comprise the same material or similar materials and are fabricated by the same process or similar processes, and after their lattice defects are repaired by a thermal processing, there is no or no obvious physical interface between the first sub insulating layer 231 and the second sub insulating layer 232. When there is no step at the interface between the first sub capacitor 2401 and the second sub capacitor 2402, e.g., there is no a second sidewall 2412 in the capacitive structure 240, there is no obvious interface between the first sub capacitor 2401 and the second sub capacitor 2402.

In some implementations, as shown in FIG. 3, an end of the second sub capacitor 2402 proximate to the transistor 210 (e.g., the bottom of the second sub capacitor 2402) has a size in the second direction smaller than that of an end of the first sub capacitor 2401 away from the transistor 210 (e.g., the top of the first sub capacitor 2401).

In some other implementations, the size of the bottom of the second sub capacitor 2402 in the x direction may be equal to the size of the top of the first sub capacitor 2401 in the x direction.

In some implementations, as shown in FIGS. 2 and 3, the contact 220 includes a connecting layer 222 and a conductive part 221, and the connecting layer 222 is located between the first active area and the conductive part 221.

In some implementations, at least a part of the capacitive structure 240 and the contact 220 are confined within one and the same opening.

As shown in FIG. 3, the capacitive structure 240 includes a first sub capacitor 2401 and a second sub capacitor 2402, with the first sub capacitor 2401 located between the second sub capacitor 2402 and the contact 220, and an extending direction of a portion of the first sidewall 2411a in the first sub capacitor 2401 proximate to the contact 220 overlapping an extending direction of a sidewall of the contact 220. In some implementations, the first sub capacitor 2401 and the contact 220 may be confined within the same one opening, and when the second sub capacitor 2402 and the first sub capacitor 2401 are formed within one and the same opening simultaneously, the second sub capacitor 2402, the first sub capacitor 2401 and the contact 220 are all confined within one and the same opening. In some other implementations, the first sub capacitor 2401 is fabricated first and then the second sub capacitor 2402 is fabricated on the first sub capacitor 2401. In this case, only the first sub capacitor 2401 and the contact 220 are confined within one and the same opening.

The contact 220 may include multiple layers of materials, for example, a conductive part 221 and a connecting layer 222. The conductive part 221 may include a material that is the same as or similar to that of the first electrode 241, e.g., tungsten. The connecting layer 222 includes a metal-semiconductor compound, for example, tungsten silicide or titanium silicide. When the semiconductor pillar 211 comprises a germanium-based semiconductor material, the connecting layer 222 may include metal germanide. The conductive part 221 is coupled to and in contact with the first electrode 241 of the capacitive structure 240 to reduce the contact resistance between the contact 220 and the first electrode 241, and provide a physical support to the capacitive structure 240, and the conductive part 221 also serves as an etch stop layer during the etching of the opening, so as to reduce damage to the transistor 210 and the connecting layer 222 during the etching; and the connecting layer 222 is coupled to and in contact with the transistor 210 to reduce contact resistance between the contact 220 and the transistor 210.

In some implementations, the contact 220 further includes a buffering layer 223, with the connecting layer 222 located between the buffering layer 223 and the conductive part 221.

The buffering layer 223 is located between the connecting layer 222 and the transistor 210. The buffering layer 223 may include silicon left after the formation of metal silicide for the connecting layer 222 and no obvious physical interface may exist between the connecting layer 222 and the buffering layer 223 in a real device. The material of the buffering layer 223 may be the same as or similar to that of the semiconductor pillar 211 to improve an adhesive power. In this implementation, the silicon may be silicon having any crystalline state, including, but is not limited to, single crystal silicon or polysilicon, or amorphous silicon or ion-doped silicon.

In some implementations, the conductivity of the connecting layer 222 is higher than that of the first active area.

The first active area includes a semiconductor material and the connecting layer 222 includes a metal compound of the semiconductor material. Illustratively, the first active area includes silicon and the connecting layer 222 includes metal silicide. In the same external environment, the resistivity of metal silicide is lower than that of silicon and the conductivity of the connecting layer 222 is higher than that of the first active area. Silicon and metal silicide are only examples, and any other semiconductor materials and semiconductor-metal compounds may be used.

In some implementations, as shown in FIG. 3, the thickness of the conductive part 221 is larger than the thickness of the connecting layer 222 in the third direction.

In the z direction, the conductive part 221 may have a larger thickness than the connecting layer 222 to ensure a good mechanical performance and a higher current load, and the connecting layer 222 may have a relatively smaller thickness to reduce the whole thickness of the contact 220.

In some implementations, in the third direction, the thickness of the conductive part 221 is larger than or equal to twice of the thickness of the connecting layer 222. The thickness difference between the conductive part 221 and the connecting layer 222 in this implementation is only an example, and other thickness differences also are comprised in the implementations of the present disclosure. Alternatively, both have the same thickness.

In some implementations, the first active area includes single crystal silicon or polysilicon; the connecting layer 222 includes metal silicide; and the buffering layer 223 includes single crystal silicon or polysilicon.

In some other implementations, the first active area may include other compounds containing silicon in the silicon-based semiconductor material, the buffering layer 223 may include the same material as the first active area, or may include a different material from the first active area, and the buffering layer 223 may also include a compound containing silicon in the silicon-based semiconductor material. The first active area and the buffering layer 223 may include a germanium-based semiconductor material, and the connecting layer 222 may include metal germanide.

In some implementations, as shown in FIGS. 2 and 3, the transistor 210 includes: a semiconductor pillar 211, the first active area located at an end of the semiconductor pillar 211 proximate to the capacitive structure 240; and a gate dielectric layer 212 and a gate 213, with the gate dielectric layer 212 located between the semiconductor pillar 211 and the gate 213.

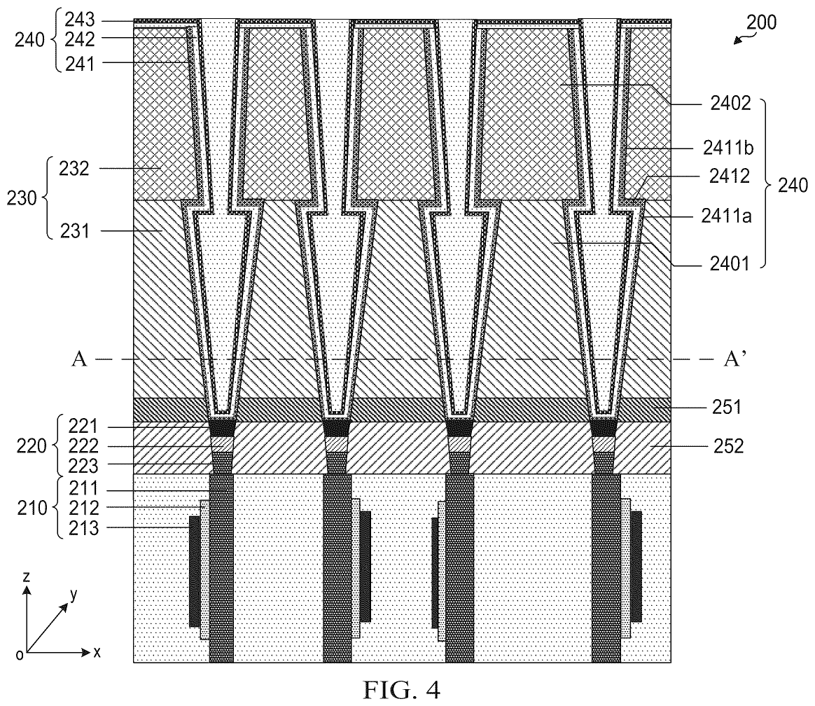

In some implementations, as shown in FIG. 4, the semiconductor structure 200 further includes a stop layer 251 located between the insulating layer 230 and the contact 220, with the capacitive structure 240 also penetrating through the stop layer 251.

In the z direction, the stop layer 251 is disposed between the insulating layer 230 and the contact 220, and has an etching rate lower than that of the insulating layer 230 during the process of etching the insulating layer 230 to form an opening therein, so that the stop layer 251 may regulate the etching rate and reduce damage to the device caused by the etching.

In some implementations, as shown in FIG. 4, the semiconductor structure further includes a transition layer 252 located between the stop layer 251 and the transistor 210. The contact 220 penetrates through the bottom of the transition layer 252 in the z direction to be coupled with the transistor 210. The top of the contact 220 is below the top of the stop layer 251 or is flush with the top of the transition layer 252. The capacitive structure 240 penetrates through the insulating layer 230 and stop layer 251 toward the transition layer 252 to be coupled with the contact 220.

The materials of the insulating layer 230, stop layer 251 and transition layer 252 in this implementation may be different from each other to regulate the etching rate of the opening and the height of the contact 220 in the z direction. Illustratively, the insulating layer 230 may include silicon oxide and the stop layer 251 may include boron silicon nitride.

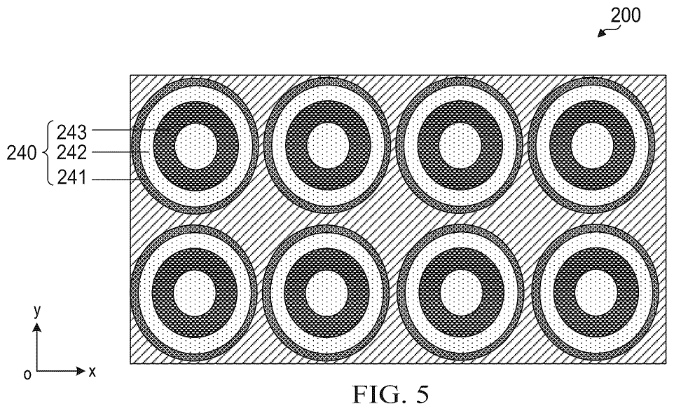

FIG. 5 shows a partial cross-sectional view of the semiconductor structure 200 in FIGS. 2 to 4 taken along the AA′ line. The arrangement of the capacitive structures 240 in shown FIG. 5 is only an example, and implementations of the present disclosure may include more capacitive structures 240.

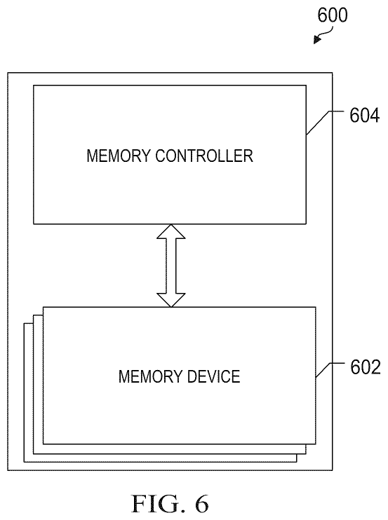

In accordance with some aspects of implementations of the present disclosure, as shown in FIG. 6, a memory system 600 is provided, including: a memory device 602 including one or more semiconductor structures 100 or 200; and a memory controller 604 coupled with and controlling the memory device 602.

Any semiconductor structure involved in the implementations of the present disclosure may be used in a subsequent fabrication process to form at least a part of the final device structure. Here, the final device may include the memory device 602.

In some examples, the semiconductor structure may be used as a computer memory or a cache in a memory system.

In some examples, the semiconductor structure may be used in a solid-state drive as an assistance to improve performance of the solid-state drive in writing/reading or other aspects. Nowadays, an embedded DRAM is often chosen for a high-end solid-state drive product to improve the product performance and random reading/writing speed. Illustratively, when a file, especially a small one, is written, it is processed by a DRAM and then stored in a flash to enable the solid-state drive to have a higher storage efficiency and a faster storage speed.

In implementations provided by the present disclosure, it should be understood that the disclosed device and method may be implemented in other non-object ways. The device implementation described above is only illustrative. For example, the units are divided according to their logic functions and may be divided in any other way in practice, e.g., multiple units or assemblies may be combined or may be integrated into another system, or some features may be neglected or not performed. Moreover, the components that have been shown or discussed may be coupled or coupled directly.

Wherever no collisions will occur, the features disclosed in the method or device implementations provided by the present disclosure may be combined as desired to obtain new method or device implementations.

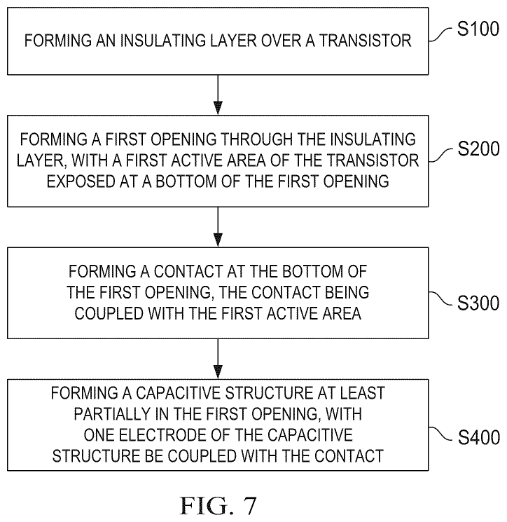

In accordance with some aspects of implementations of the present disclosure, FIG. 7 provides a schematic flowchart of a method of fabricating a semiconductor structure 200. The method includes: forming an insulating layer over a transistor; forming a first opening through the insulating layer, with a first active area of the transistor exposed at a bottom of the first opening; forming a contact at the bottom of the first opening, the contact being coupled with the first active area; and forming a capacitive structure at least partially in the first opening, with one electrode of the capacitive structure being coupled with the contact.

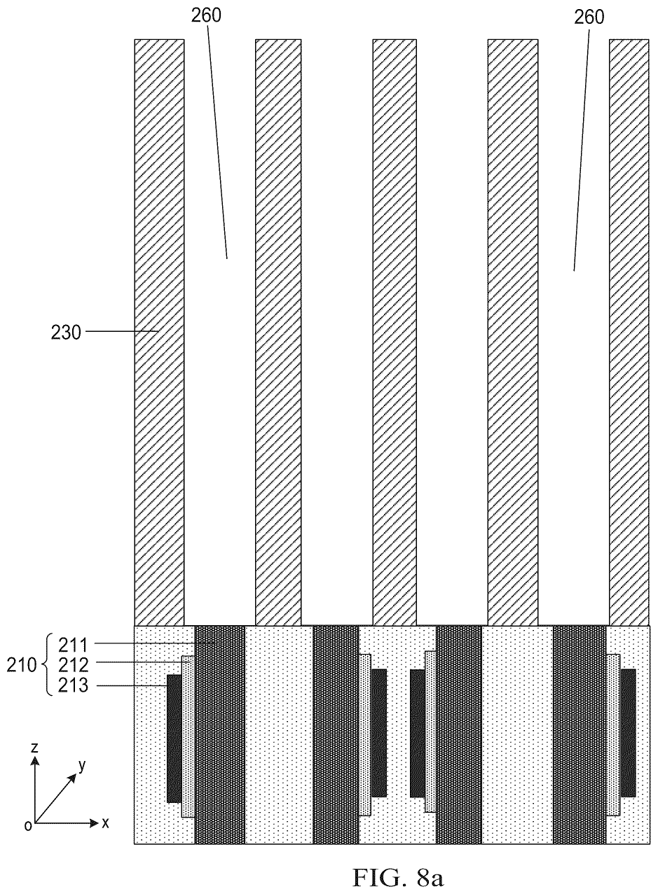

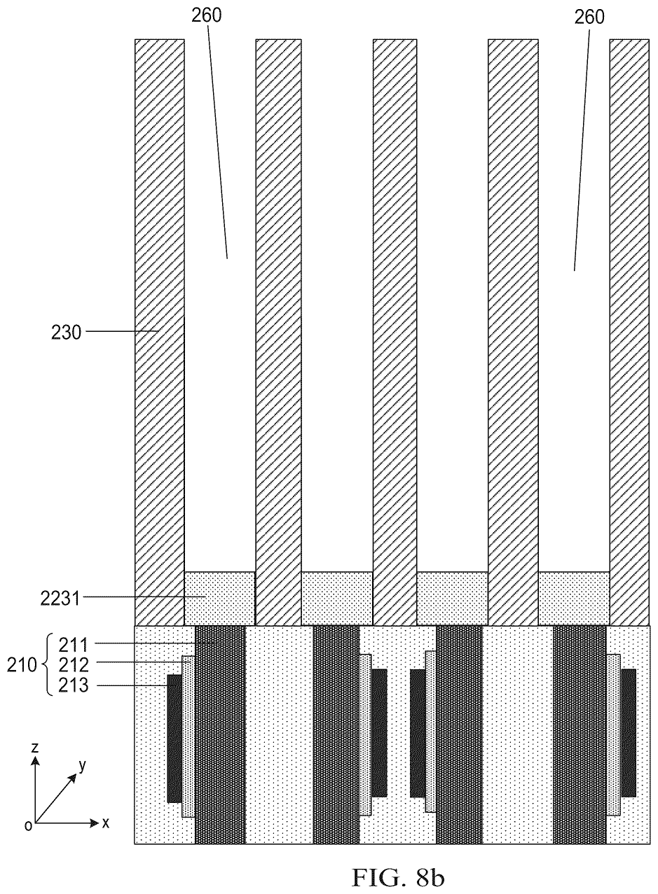

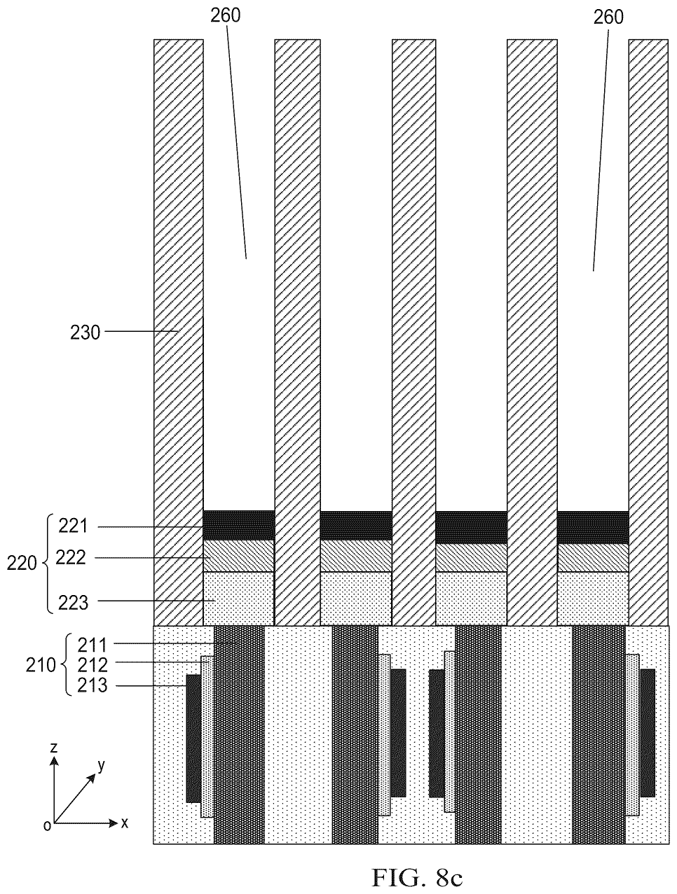

In an example, as shown in FIG. 8a, a preformed structure with a transistor 210 is provided, an insulating layer 230 is deposited on the transistor 210, and a first opening 260 is formed through the insulating layer 230. The first active area of the transistor 210 is exposed at the bottom of the first opening 260.

The contact 220 including a conductive material is formed at the bottom of the first opening 260 by deposition, and is coupled with the first active area. In some implementations, the operation of forming the contact 220 in the first opening 260 includes: forming a layer of buffering material 2231 at the bottom of the first opening 260; forming a layer of metal material on and in contact with the layer of buffering material 2231; thermally treating the layer of buffering material 2231 and the layer of metal material, both at least a part of the layer of buffering material 2231 and the layer of metal material forming the connecting layer 222; and forming a conductive part 221 on the connecting layer 222.

As shown in FIG. 8b, a buffering material is filled in the first opening 260, and is removed partially to leave the buffering material at the bottom of the first opening, so that a layer of buffering material 2231 is formed at the bottom of the first opening 260, with the layer of buffering material 2231 including a semiconductor material. As shown in FIG. 8c, a layer of metal material is deposited on the layer of buffering material 2231, and the layer of buffering material 2231 and the layer of metal material are thermally treated. At the interface between the layer of buffering material 2231 and the layer of metal material, the layer of buffering material 2231 and the layer of metal material react to generate a semiconductor-metal compound that forms the connecting layer 222. The connecting layer 222 includes, but is not limited to, titanium silicide, titanium germanide, tungsten silicide, tungsten germanide or the like. After a capacitive structure 240 is formed in the opening 260 as shown in FIG. 8c, the semiconductor structure 200 shown in FIG. 2 is obtained.

Illustratively, the etching process may include, but is not limited to, dry etching, wet etching or a combination thereof.

In some implementations, when silicon and titanium are taken as an example, the layer of buffering material 2231 comprises silicon and a layer of titanium is formed on the layer of silicon. Then the layer of silicon and the layer of titanium are thermally treated to form titanium silicide (the connecting layer 222). By reducing the thickness of the deposited layer of silicon or increasing the amount of time for thermal processing, the whole layer of silicon may react to form titanium silicide. Alternatively, by increasing the thickness of the deposited layer of silicon or reducing the amount of time for thermal processing, a part of the layer of silicon may react to form titanium silicide and the remaining silicon forms a buffering layer 223 coupled with and in contact with the transistor 210, so that adhesive power may be increased, and contact stress may be reduced. There is no obvious physical interface between the buffering layer 223 and the connecting layer 222.

In some other implementations, a part of the layer of metal material left without forming metal silicide may serve as a part of the conductive part 221. The conductive part 221 and the layer of metal material may comprise the same material, e.g., both of them comprise titanium or tungsten, or may comprise different materials.

In some implementations, the first active area includes single crystal silicon or polysilicon, the connecting layer 222 includes metal silicide, and the layer of buffering material 2231 includes single crystal silicon or polysilicon.

In some implementations, the operation of forming the capacitive structure 240 includes: as shown in FIG. 2, forming a first electrode 241, a dielectric layer 242 and a second electrode 243 sequentially over a sidewall and bottom of each of a plurality of first openings 260, wherein the first electrodes 241 are electrically isolated from each other, the second electrode 243 continuously covers sidewalls and bottoms of the plurality of first openings 260, and the plurality of capacitive structures 240 are coupled by the second electrode 243.

Illustratively, the process of forming the dielectric layer 242 may be any process as well known in the art including, but is not limited to, a low temperature chemical vapor deposition, low pressure chemical vapor deposition, rapid thermal chemical vapor deposition, atomic layer deposition, plasma-enhanced chemical vapor deposition, or the like. The process of forming the first electrode 241 and the second electrode 243 may include a physical deposition process in addition to the above mentioned chemical deposition process.

In FIG. 2, after the dielectric layer 242 is formed and when the second electrode 243 is formed by filling a conductive material into the first opening 260, the conductive material does not fill up the first opening 260. For example, after the formation of the second electrode 243, the first opening 260 is not filled up. An insulating material is then filled into the remaining space in the first opening 260, to form a core with a void therein. The second electrode 243 surrounds a side and bottom of the dielectric layer 242 to support the capacitive structure 240. The dielectric layer 242 extends continuously over sidewalls and bottoms of a plurality of first openings 260. The second electrode 243 covers the dielectric layer 242 and is conformal to the dielectric layer 242, and extends continuously over a plurality of capacitive structures 240 so that one second electrode 243 is shared by the plurality of capacitive structures 240 and the second electrode 243 is grounded or supplied with the voltage of Vcc/2, which avoids respectively forming pads or conductive plugs to respectively supply power to individual second electrodes 243 of the plurality of capacitive structures 240. Therefore, the fabrication cost is reduced, the area of the second electrode 243 is also increased, the voltage/current load is increased, and the reliability is improved.

In some other implementations, after the formation of the dielectric layer 242, a conductive material is filled into a remaining space of the first opening 260 to occupy all of the remaining space, so that the second electrode 243 has a shape of cylinder. In this way, the second electrode 243 has an increased voltage/current load and also provides a support to the capacitive structure 240.

As shown in FIGS. 8a to 8c, when the first opening 260 has a relatively smaller depth in the z direction or has a relatively smaller aspect ratio, the loading effect of the etching is relatively smaller, so that the difference in sizes between the top and the bottom of the first opening 260 in the x direction is relatively smaller. The difference in sizes between the top and the bottom of the capacitive structure 240 as shown in FIG. 2 in the x direction is also relatively smaller, achieving a better uniformity.

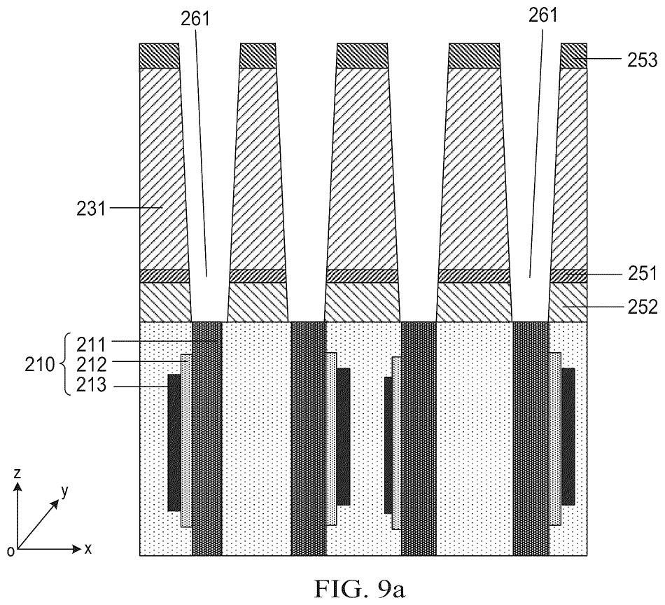

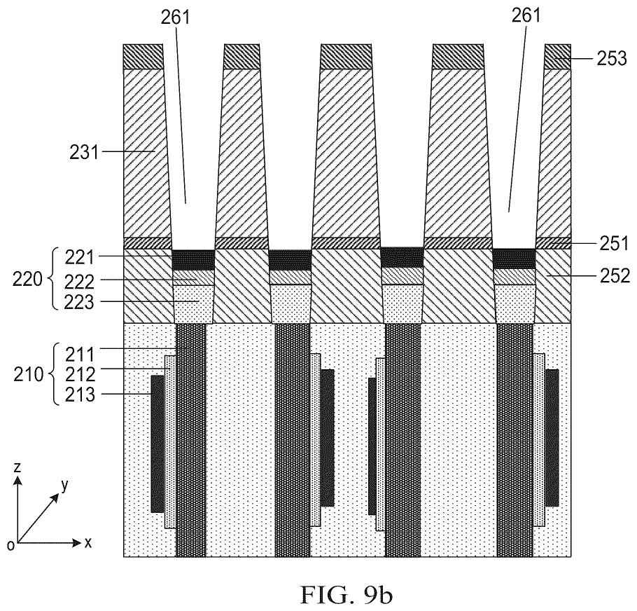

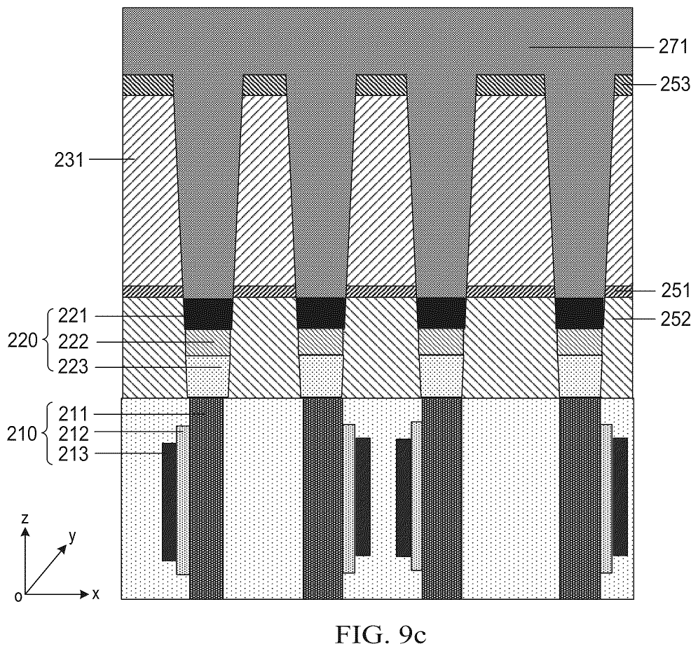

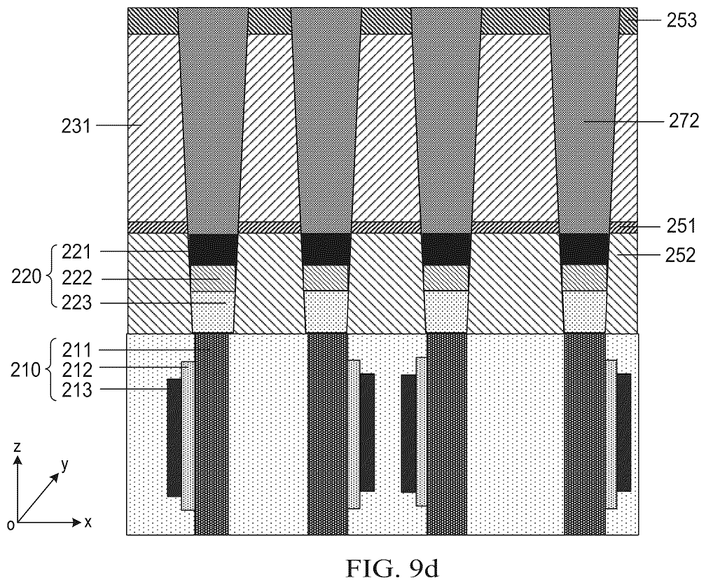

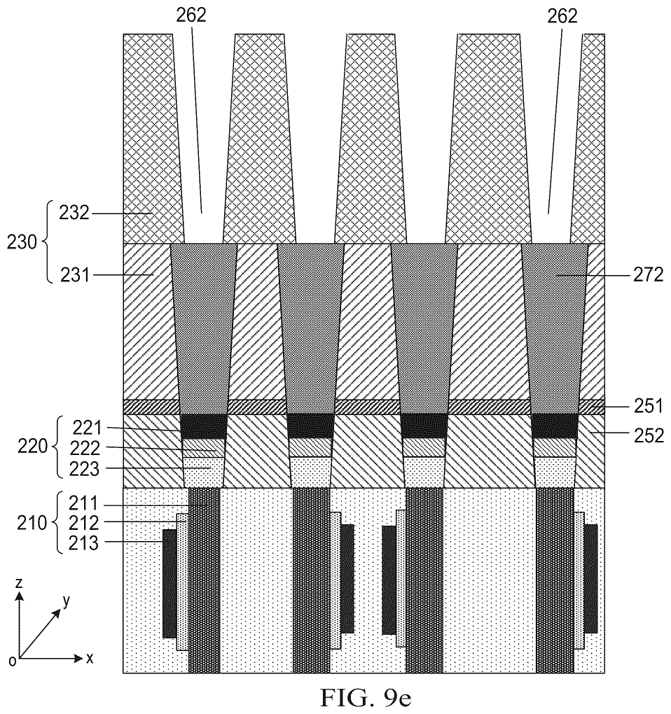

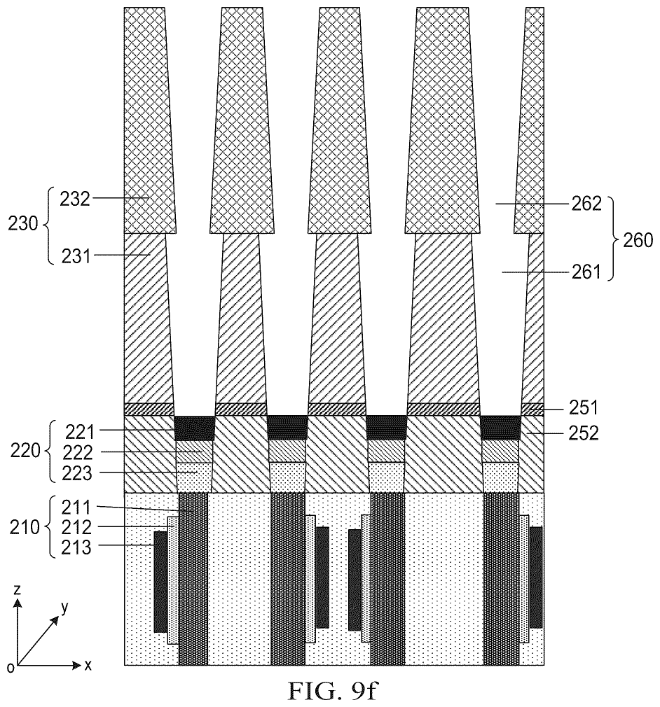

In some implementations, when the first opening 260 has a relatively larger depth in the z direction or has a relatively larger aspect ratio, the loading effect of the etching is relatively larger, so that the size of the top of the first opening 260 in the x direction is larger than the size of the bottom of the first opening 260 in the x direction. Since the depth of the first opening 260 is relatively larger, the etching may take several steps. For example, a first sub opening 261 may be etched first, and a second sub opening 262 is etched subsequently to reduce the aspect ratio for each etching. With reference to FIG. 9a, a first sub insulating layer 231 is formed on the transistor 210, and a first sub opening 261 is formed through the first sub insulating layer 231, wherein the size of the top of the first sub opening 261 in the x direction is larger than the size of the bottom of the first sub opening 261 in the x direction.

In some implementations, the first opening 260 includes a first sub opening 261 and a second sub opening 262. The operation of forming the first opening 260 includes: forming a first sub opening 261 through the first sub insulating layer 231, with the first active area of the transistor 210 exposed at the bottom of the first sub opening 261; forming a contact 220 at the bottom of the first sub opening 261, with the contact 220 being coupled with the first active area; forming a sacrificial part 272 in the first sub opening 261 having the contact 220 therein, with a top surface of the sacrificial part 272 flush with the first sub insulating layer 231; forming a second sub insulating layer 232 on the first sub insulating layer 231 and the sacrificial part 272; forming a second sub opening 262 through the second sub insulating layer 232 in the third direction, with the sacrificial part 272 exposed at the bottom of the second sub opening 262; and removing the sacrificial part 272 to make the first sub opening 261 be exposed by the second sub opening 262.

In an example, as shown in FIG. 9a, the first sub insulating layer 231 is formed over the transistor 210, and may include multiple layers of materials or a single layer of material; a transition layer 252 and a stop layer 251 are formed between the first sub insulating layer 231 and the transistor 210, with the transition layer 252 located between the stop layer 251 and the transistor 210; and a blocking layer 253 is formed on the first sub insulating layer 231. The transition layer 252 and the stop layer 251 are configured to regulate the etching rate and the blocking layer 253 is configured to protect the first insulating layer 230. A first sub opening 261 is formed through the blocking layer 253, the first sub insulating layer 231, the stop layer 251 and the transition layer 252 by etching, and exposes the first active area of the transistor 210.

As shown in FIG. 9b, a contact 220 is formed at the bottom of the first sub opening 261 and has a top, which is below a top of the stop layer 251 in the z direction or is flush with a top of the transition layer 252. Illustratively, the insulating layer 230 may include silicon oxide, the stop layer 251 may include boron silicon nitride, and the blocking layer 253 may include carbon silicon nitride.

In some implementations, when the contact 220 is formed by deposition, a process gas for forming the contact 220 has an affinity for the transition layer 252 and thus has a relatively larger adhesive power with the transition layer 252, whereas the process gas for forming the contact 220 does not have an affinity for the stop layer 251 and thus has a smaller adhesive power with the stop layer 251. Therefore, a larger portion of the contact 220 is formed in a part of the opening within the transition layer 252 and thus a height of the contact 220 in the z direction is controlled to reduce the occupancy of the space for formation of the capacitive structure 240 by the contact 220.

As shown in FIG. 9c, a layer of sacrificial material 271 is filled into the first sub opening 261, wherein the first sub opening 261 is filled up with the layer of sacrificial material 271, and the layer of sacrificial material 271 also covers a surface of the blocking layer 253. As shown in FIG. 9d, a top of the structure shown in FIG. 9c is planarized to remove a part of the layer of sacrificial material 271 covering the blocking layer 253. Then, the blocking layer 253 on the first sub insulating layer 231 is removed. The remaining part of the layer of sacrificial material 271 in the first sub opening 261 forms a sacrificial part 272, with a top of the sacrificial part 272 flush with a top of the first sub insulating layer 231. Illustratively, the planarization process includes, but is not limited to, dry etching, wet etching, chemical mechanical grinding or any combination thereof.

As shown in FIG. 9e, a second sub insulating layer 232 is formed on the first sub insulating layer 231 and the sacrificial part 272, and a second sub opening 262 is formed through the second sub insulating layer 232 in the z direction, with the sacrificial part 272 exposed at the bottom of the second sub opening 262 respectively. Due to the loading effect of etching, the size of the top of the second sub opening 262 in the x direction is larger than the size of the bottom of the second sub opening 262 in the x direction.

As shown in FIG. 9f, the sacrificial part 272 in the first sub opening 261 is etched and removed by means of the second sub opening 262, and the second sub opening 262 and the first sub opening 261 may communicate with each other in the z direction so as to form a first opening 260. The size of the bottom of the second sub opening 262 in the x direction is smaller than the size of the top of the first sub opening 261 in the x direction. At the interface between the first sub insulating layer 231 and the second sub insulating layer 232, the bottom of the second sub opening 262 and the top of the corresponding first sub opening 261 are aligned and a step is formed.

In some implementations, as shown in FIG. 9f, at the interface between the first sub insulating layer 231 and the second sub insulating layer 232, the first opening 260 has a third sidewall extending in the first direction and a fourth sidewall extending in the second direction that crosses the first direction and is perpendicular to the penetrating direction of the first opening 260. The fourth sidewall extends along the interface between the first sub insulating layer 231 and the second sub insulating layer 232.

In FIG. 9f, the third sidewall and the fourth sidewall may be defined with respect to the whole first opening 260 comprising the first sub opening 261 and the second sub opening 262, and the third sidewall may have a part in the first sub opening 261 and a part in the second sub opening 262. The fourth sidewall is located at the interface between the first sub insulating layer 231 and the second sub insulating layer 232, may be a part of the bottom of the second sub insulating layer 232 that extends in the x direction, and is exposed in the first opening 260. The fourth sidewall may serve as a boundary between the first sub opening 261 and the second sub opening 262. The third sidewall may extend in the z direction or in a direction at an angle with respect to the z direction. The extending direction of the third sidewall runs through the xoy plane.

In some implementations, the capacitive structure 240 is formed in the opening 260 shown in FIG. 9f, resulting in the semiconductor structure 200 as shown in FIG. 4.

In some implementations, in the second direction (the x direction), the size of the bottom of the second sub opening 262 is smaller than the size of the top of the first sub opening 261.

In some implementations, the operation of forming the transistor 210 includes: forming a semiconductor pillar 211 by etching a semiconductor layer 20; forming a gate dielectric layer 212 at a side of the semiconductor pillar 211; forming a gate 213 covering the gate dielectric layer 212, with the gate dielectric layer 212 located between the semiconductor pillar 211 and the gate 213; and forming a first active area by doping an end of the semiconductor pillar 211.

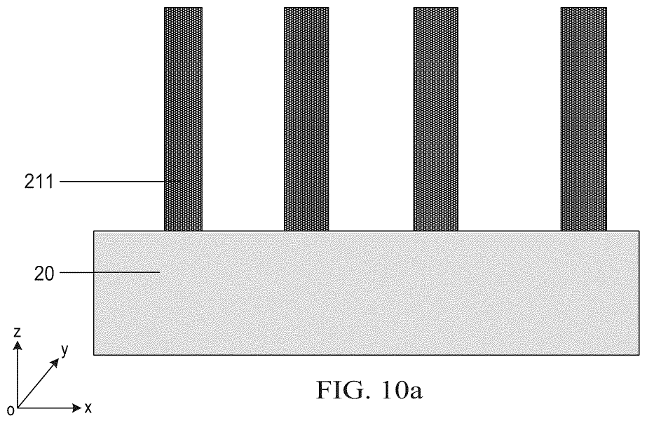

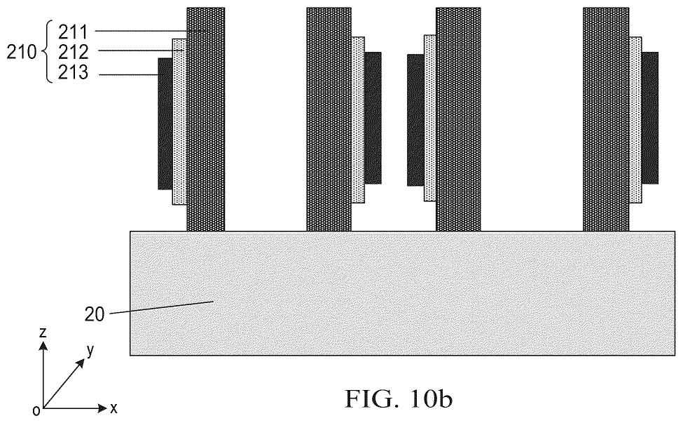

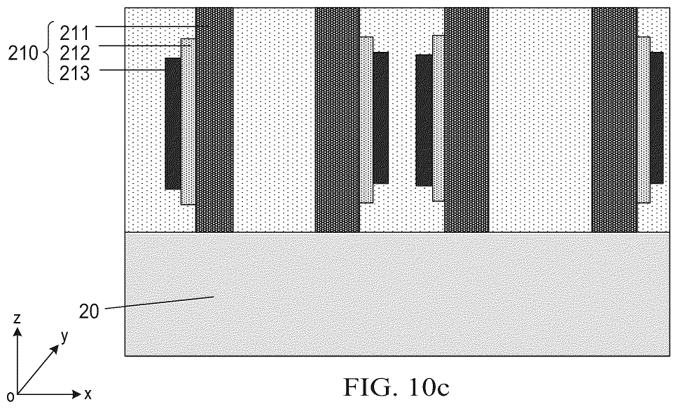

In an example, a substrate is provided, and a semiconductor layer 20 is formed on the substrate and is etched to form a semiconductor pillar 211 as shown in FIG. 10a. The semiconductor pillars 211 may be arranged in an array. The semiconductor pillar 211 may be n-type doped at opposite ends in the z direction to form a first active area and a second active area. The region of the semiconductor pillar 211 between the first and second active areas is p-type doped to form a channel. In some implementations, the semiconductor layer 20 is p-type doped. The semiconductor pillar 211 is n-type doped only at opposite ends to form the first and second active areas. The remaining portion of the semiconductor pillar 211 is a p-type channel. In some implementations, the first and second active areas may be p-type doped, and the channel is n-type doped.

In some implementations, the substrate may be a semiconductor substrate and may be etched directly to form the semiconductor pillar 211. In FIG. 10a, a layer of material below the semiconductor pillar 211 is labeled as a semiconductor layer 20 (a substrate).

As shown in FIG. 10b, a gate dielectric layer 212 is formed at a side of the semiconductor pillar 211, and the gate dielectric layer 212 may cover one side of the semiconductor pillar 211 or surround four sides of the semiconductor pillar 211. A gate 213 is formed on the dielectric layer 212, and the gate 213 may cover one side of the semiconductor pillar 211 or surround four sides of the semiconductor pillar 211. As shown in FIG. 10c, an insulating material is filled into the gaps between the transistors 210 to provide a support to the transistors 210.

In some implementations, the semiconductor layer 20 is thinned from a bottom of the semiconductor layer 20 in the z direction so that the semiconductor layer 20 has a smaller thickness, or the semiconductor layer 20 is removed.

In some implementations, a bit line is formed at the bottom of the semiconductor pillar 211 in the z direction, wherein the bit line is coupled with the second active area of the transistor 210.

What have been described above are only specific implementations of the present disclosure. However, the scope of the present disclosure is not limited thereto, and variations or substitutions that easily occur to those skilled in the art in light of the technical contents disclosed by the present disclosure will fall within the scope of the present disclosure. Therefore, the scope of the present disclosure should be determined by the scope of the claims.

What is claimed is:

1. A semiconductor structure, comprising:
a transistor;
a contact located on the transistor and coupled with a first active area of the transistor; and
a capacitive structure located over the contact, wherein an extending direction of a sidewall of the capacitive structure at an end proximate to the contact overlaps an extending direction of a sidewall of the contact, and one electrode of the capacitive structure is coupled with the contact.

2. The semiconductor structure of claim 1, wherein at least a part of the capacitive structure and the contact are confined within one and the same opening.

3. The semiconductor structure of claim 1, wherein the contact comprises a connecting layer and a conductive part, and the connecting layer is located between the first active area and the conductive part.

4. The semiconductor structure of claim 1, wherein the capacitive structure comprises:
a first sub capacitor and a second sub capacitor; and
a first sidewall extending in a first direction and a second sidewall extending in a second direction crossing the first direction, wherein the second sidewall extends along an interface between the first sub capacitor and the second sub capacitor.

5. The semiconductor structure of claim 4, further comprising an insulating layer located over the first active area, wherein the capacitive structure penetrates through the insulating layer.

6. The semiconductor structure of claim 5, wherein the insulating layer comprises a first sub insulating layer and a second sub insulating layer, the first sub insulating layer is located between the second sub insulating layer and the contact, the first sub capacitor penetrates through the first sub insulating layer in a third direction perpendicular to the second direction and is coupled with the contact, the second sub capacitor penetrates through the second sub insulating layer in the third direction, and the second sidewall extends along an interface between the first sub insulating layer and the second sub insulating layer.

7. The semiconductor structure of claim 6, wherein a size of the second sub capacitor at an end proximate to the transistor in the second direction is smaller than a size of the first sub capacitor at an end away from the transistor in the second direction.

8. The semiconductor structure of claim 3, wherein a thickness of the conductive part is larger than a thickness of the connecting layer in a third direction.

9. The semiconductor structure of claim 8, wherein the thickness of the conductive part is larger than or equal to twice of the thickness of the connecting layer in the third direction.

10. The semiconductor structure of claim 3, wherein the contact further comprises a buffering layer, and the connecting layer is located between the buffering layer and the conductive part.

11. The semiconductor structure of claim 10, wherein the first active area comprises single crystal silicon or polysilicon, the connecting layer comprises metal silicide, and the buffering layer comprises single crystal silicon or polysilicon.

12. The semiconductor structure of claim 1, wherein the capacitive structure comprises: a first electrode, a dielectric layer and a second electrode disposed sequentially, wherein the first electrode is coupled with the contact, and a plurality of the capacitive structures are coupled by the second electrode.

13. A memory system, comprising:
a memory device comprising:
a transistor;
a contact located on the transistor and coupled with a first active area of the transistor; and
a capacitive structure located over the contact, wherein an extending direction of a sidewall of the capacitive structure at an end proximate to the contact overlaps an extending direction of a sidewall of the contact, and one electrode of the capacitive structure is coupled with the contact; and
a memory controller coupled with the memory device and controlling the memory device.

14. A method of fabricating a semiconductor structure, comprising:
forming an insulating layer over a transistor;
forming a first opening through the insulating layer, a first active area of the transistor exposed at a bottom of the first opening;
forming a contact at the bottom of the first opening, the contact being coupled with the first active area; and
forming a capacitive structure at least partially in the first opening, one electrode of the capacitive structure being coupled with the contact.

15. The method of claim 14, wherein the first opening comprises a first sub opening and a second sub opening, and the forming the first opening comprises:
forming the first sub opening through the first sub insulating layer, the first active area of the transistor exposed at a bottom of the first sub opening;
forming the contact at the bottom of the first sub opening, the contact being coupled with the first active area;
forming a sacrificial part in the first sub opening having the contact therein, a top surface of the sacrificial part being flush with the first sub insulating layer;
forming a second sub insulating layer on the first sub insulating layer and the sacrificial part;
forming the second sub opening through the second sub insulating layer in a third direction, wherein the sacrificial part is exposed at a bottom of the second sub opening; and
removing the sacrificial part so that the first sub opening is exposed by the second sub opening; and
wherein the first opening has a third sidewall extending in a first direction and a fourth sidewall extending in a second direction that crosses the first direction, and the second direction is perpendicular to a penetrating direction of the first opening, wherein the fourth sidewall extends along an interface between the first sub insulating layer and the second sub insulating layer.

16. The method of claim 15, wherein a size of a bottom of the second sub opening is smaller than a size of a top of the first sub opening in the second direction.

17. The method of claim 14, wherein the forming the capacitive structure comprises:
forming a first electrode, a dielectric layer and a second electrode sequentially over a sidewall and a bottom of each of a plurality of the first openings, wherein the first electrodes are electrically isolated from each other, the second electrode continuously covers sidewalls and bottoms of a plurality of the first openings, and a plurality of the capacitive structures are coupled by the second electrode.

18. The method of claim 14, wherein the forming the contact comprises:
forming a layer of buffering material at a bottom of the first opening;
forming a layer of metal material on and in contact with the layer of buffering material;
thermally treating the layer of buffering material and the layer of metal material, both at least a part of the layer of buffering material and the layer of metal material forming a connecting layer; and
forming a conductive part on the connecting layer.

19. The method of claim 18, wherein:
the first active area comprises single crystal silicon or polysilicon;
the connecting layer comprises metal silicide; and
the layer of buffering material comprises single crystal silicon or polysilicon.

20. The method of claim 14, wherein the forming the transistor comprises:
forming a semiconductor pillar by etching a semiconductor layer;
forming a gate dielectric layer at a side of the semiconductor pillar;
forming a gate covering the gate dielectric layer, wherein the gate dielectric layer is located between the semiconductor pillar and the gate; and
forming the first active area by doping an end of the semiconductor pillar.
